(19) United States
(12) Patent Application Publication
(10) Pub. No.: US 2007/0224768 A1
(43) Pub. Date: Sep. 27, 2007

(54) Method and apparatus for delivery of pulsed laser radiation

(75) Inventors: Victoria M. Chaplick, Webster, MA (US); Kenneth J. Harte, Carlisle, MA (US); Ronald P. Millman JR., Taunton, MA (US); David J. Elliott, Wayland, MA (US)

Correspondence Address: MILLS & ONELLO LLP, ELEVEN BEACON STREET, SUITE 605, BOSTON, MA, 02108, US

(73) Assignee: UVTech Systems, Inc., Sudburry, MA (US)

(21) Appl. No.: 11/710,094

(22) Filed: Feb. 23, 2007

Related U.S. Application Data
(60) Provisional application No. 60/776,211, filed on Feb. 24, 2006.

(51) Int. Cl. H01L 21/336

(52) U.S. Cl. 438/308; 257/E21.517

(57) ABSTRACT

A method and apparatus delivers pulsed laser energy to a damage-sensitive surface. The pulse scanning method and apparatus allow for the deposition of a total dose of laser radiation that could not be attained by any conventional means without damaging the substrate being exposed. Using a solid-state diode pumped YAG laser and an enclosure with a gas ambient, laser pulses are scanned across a substrate according to one of several programmed approaches. Pulses are deposited that are non-adjacent in time, or non-adjacent in space, or both; conventional methods have the pulses adjacent in both time and space. Using the various approaches of the invention, the degree of spatial and temporal adjacency can be precisely controlled to permit significant laser radiation doses without causing any substrate damage. The present invention novel method and apparatus can be carried out by integrating a computer, laser and scan head with a small chamber into which gas can flow to permit a variety of surface reactions on damage-sensitive substrates that could otherwise not be conducted with conventional methods and systems.

### RELATED APPLICATION

This application is related to U.S. Provisional Patent Application Ser. No. 60/776,211, filed in the U.S. Patent and Trademark Office on Feb. 24, 2006, the entire contents of which are incorporated herein by reference.

### FIELD OF THE INVENTION

The present invention relates generally to a method and apparatus for the treatment of damage-sensitive surfaces with pulsed laser radiation. The present invention provides a novel method and apparatus for processing substrates with laser light using a number of pulse delivery approaches that permit laser radiation to be evenly deposited so as to prevent damage to the substrate. The invention is directed toward a method and apparatus for producing laser and gas reactions on damage-sensitive surfaces, such as for advanced semiconductor wafer processes and optical thin film surfaces. It finds particular application for damage-free treatment and conditioning of delicate surfaces used in the fabrication of semiconductor and optical devices including integrated circuits, thin film heads, optical disks, and flat panel displays.

### BACKGROUND OF THE INVENTION

Processing of materials with pulsed laser radiation has become commonplace over the past decade, mainly due to improvements in solid-state laser and gas laser technology. Applications for pulsed lasers include drying, curing, imaging, cleaning, annealing, oxidizing, marking and micro-machining. The energy density, or fluence, required to successfully process these applications varies from as little as 2-3 mJ/cm² to over 1,000 mJ/cm². The required energy density is determined by several factors, including the properties of the material being processed, the laser wavelength and its spectral coupling into the substrate and/or contaminate layer, the ambient gas during exposure, and process temperature and pressure. Since most laser beams are smaller than the work piece or substrate, they need to be scanned or stepped across the surface of the substrate to obtain full coverage. Therefore the substrate and beam are moved relative to each other to fully expose the entire substrate.

Current processes may use a scanning beam that sweeps back and forth across a substrate, or a fixed beam and moving substrate, or both moving, all to obtain full laser beam coverage. A conventional method of this type is illustrated in FIG. 1a. Referring to FIG. 1a, a semiconductor wafer 10 is scanned back and forth in a series of passes or sweeps until the entire substrate is exposed. Each individual pulse 14 is represented by a circle, as most solid state laser beams are circular in shape. In order to obtain maximum coverage of the beam on the substrate, pulses are typically overlapped, creating an overlap zone 16, illustrated in FIG. 1b. This is the simplest and the most common way to expose substrates to pulsed laser radiation.

As each pulse is deposited in sequence, and with some overlap, heat is accumulated in the substrate. If the total deposited energy density on and in the substrate becomes too great, it reaches the damage threshold. This effect is illustrated in FIGS. 2a and 2b. The occurrence of this effect is determined by the pulse repetition rate, by the residence time of this energy measured in terms of its thermal energy half-life, the thermal diffusion time, the thermal diffusion length that is a function of time, and by the process's proximity to the damage threshold of the substrate. If laser pulses are deposited such that they are too adjacent in time and/or space, such that the time between pulses is less than the thermal diffusion time, there is the potential for damage to the substrate.

Laser pulse damage is caused by energy being deposited, adjacent in time and space, on and into the substrate. The degree of damage is partly dependent on the thermal energy half-life or residence time measured in milliseconds. As each pulse is deposited, some energy is stored in the substrate or the contaminate layer being removed from the substrate, and begins to dissipate over time. Since solid state pulsed lasers can deposit pulses at repetition rates of 10 kHz to 100 kHz, with individual pulse energies of 0.1-1.0 mJ, significant heat energy can be accumulated in the substrate. As sequential pulses are deposited, the energy accumulates to exceed the damage threshold of the substrate. This is the reason that primary applications for the YAG solid state pulsed lasers include micromachining, including very tough materials such as stainless steel.

In an attempt to solve this problem, the pulse overlap can be eliminated by spreading pulses out, but this creates a larger problem of incomplete laser coverage of the substrate. Referring to FIG. 1c, a semiconductor wafer has been exposed to a scanning beam and the pulses 18 have been separated sufficiently to eliminate the overlap zone. Unfortunately, the pulse separation used to avoid the overlap ‘damage’ zone results in a larger zone of untreated substrate 20. The area left unexposed, when the pulses are not overlapped, is typically approximately 9%.

In a cleaning application, incomplete coverage results in incomplete cleaning, which is unacceptable and may require a second or third pass, greatly increasing the processing time. In some cases complete cleaning is not possible without a better method of placing the laser pulses. In an oxidation reaction, separated pulses will leave areas of very thin or nonexistent oxide, while the balance of the substrate will have the correct amount of oxidation.

Thus to obtain complete coverage with a round beam, pulses are overlapped. This results in an overlap zone where pulses are adjacent in both time and space where the heat from the deposited laser energy is not able to completely dissipate before the next pulse deposits its energy in the same location. The problem is reduced but not eliminated by the use of square or hexagonal beams, since small but unavoidable errors in beam placement inevitably result in skipped or overradiated regions between pulses.

In processing of delicate or sensitive surfaces, including for example the manufacture of semiconductor devices, thin film heads, optical thin film devices, and flat panel display substrates, this overlap zone will cause a number of unwanted effects which are application dependent. The following are specific examples of the problems of the related art with respect to laser beam processing.

Firstly, in curing of light sensitive films, the overlap zone will result in an unwanted change in chemical properties of the film from heat buildup, causing an unacceptable dimensional change in the image.

Secondly, in the process of oxidation or oxide or other film growth on a substrate, the temporal and spatial adjacency of pulses will create non-uniformity in the growth of the film that is unacceptable. In the most extreme cases this energy buildup may result in ablation of the oxide layer. In IC manufacturing, it is critical that films have uniform thickness for reliable electrical performance.

Thirdly, in cleaning applications, the increase in fluence in the overlap zone will result in physical damage to the underlying substrate in the form of cracking, melting, ablation, or other unwanted changes to the substrate. If the substrate is ablated, the loose particles can contaminate the substrate. Additionally, if pulses that are sequential in time occur too close together in space, the resulting reactions will compete for the same portions of the surrounding reactive gas atmosphere resulting in a situation in which the reaction is gas starved and will not be able to proceed to completion.

Another cleaning problem with pulsed laser processing occurs when contaminates removed from thin conductive films are placed on top of thicker less conductive or insulating films. This situation occurs in integrated circuit fabrication, mask making, thin film head manufacturing, and in optical disc processing. The difference in thermal expansion between two films causes, for example, a thin top layer to stress and crack when exposed to laser radiation. This will occur on substrates having a thin, highly conductive layer, such as a metal, on top of an insulator, such as glass, silicon dioxide, silicon, or a similar semi-conducting or insulating material.

When exposed to laser radiation the conductive thin film on top of insulating layer will generate stress lines and open cracks causing shorts. In semiconductor processing, film thicknesses of 2-3 nm (or 20-30 Å) are used. These films are extremely damage-sensitive to all forms of intense radiation and any mechanical stresses, and conventional surface processing methods, such as wet cleaning or ashing, will not reliably produce damage-free results.

Fourthly, in the use of laser processing to cure films, there is often a threshold reaction temperature above which excessive curing or overheating produces undesirable effects. There is a need to generate a uniform, well controlled thermal curing environment in, for example, the formation of low-k films used in advanced semiconductor devices. Laser pulses, placed next to each other as in the related art, will result in very high, non-uniform energy profiles that may overcure the films being processed.

A fifth problem with laser processing is the cost and complexity of the equipment used to deliver laser radiation to surfaces. Systems of the related art have generally large footprints that consume expensive factory or clean room floor space. Further, the combined size and complexity of the lasers and optical systems makes the process expensive and prevents the expanded use of laser technology in general for cost reasons. As a result, many processes that could otherwise benefit from the advantages of laser processing are not used.

### SUMMARY OF THE INVENTION

The present invention is therefore directed to a laser pulse scanning method and apparatus that will substantially overcome one or more of the problems due to the limitations and disadvantages of the related art.

It is a general feature of the present invention to provide a pulsed laser scanning method and apparatus that eliminates the problem of temporal and spatial pulse adjacency, and therefore eliminates the problems of the related art cited above.

It is therefore a feature of the present invention to provide a method and apparatus of pulsed laser radiation that solves the problem of excessive heat build-up and non-uniform heat distribution in the processes used for the curing of light-sensitive films or other polymer coatings used in lithography or IC manufacturing, and provides the deposition of laser energy that allows for uniform thermal curing. It is also a feature of the present invention to provide this uniformity without imparting significant heat into the bulk of the substrate as in the related art.

It is another feature of the present invention to provide a method and apparatus of pulsed laser radiation that permits the uniform oxidation of films such as copper in the manufacture of ICs or other devices requiring the growth of thin, uniform films using laser radiation and gas.

It is another feature of the present invention to provide a method and apparatus for delivering pulsed laser radiation for cleaning surfaces, wherein the pulsed laser energy is delivered uniformly in both temporal and spatial space. This is especially critical in cleaning thin conductive films on less conductive or insulating surfaces. In cleaning applications, it is also a feature of the present invention to provide a method of separating the laser pulses temporally and spatially to solve the problem of gas starvation in reactions where the reaction within each ablation plume consumes large amounts of gas.

It is another feature of the present invention to provide a method and apparatus for delivering pulsed laser radiation for the uniform curing of films, such as needed in the formation of low-k films in advanced IC fabrication.

It is another feature of the present invention to provide a system for delivering pulsed laser radiation that is simple, low cost, and reliable in manufacturing environments.

Therefore, according to the present invention, there is provided multiple scanning approaches that distribute pulsed laser radiation both spatially and temporally in a way to solve the problems of the related art.

According to the invention, there is also provided a, low-cost and small-footprint system that includes a laser, a scan head, an enclosure allowing gas flow over the substrate, with a window to allow the beam to enter, and a computer/processor/controller to execute the pulsed laser scanning approaches of the present invention.

According to a first aspect, the present invention is directed to a method for delivering pulsed laser energy to a substrate. The method includes applying the pulsed laser energy to the substrate; and spatially and temporally separating pulses of the pulsed laser energy on the substrate by performing multiple interleaved scans of the pulsed laser energy onto the substrate.

In one embodiment, pulse separation reduces thermally induced damage during laser cleaning of a substrate. In one embodiment, pulse separation reduces gas depletion during laser cleaning in a reactive gas atmosphere. In one embodiment, pulse separation reduces unwanted thermally induced change in chemical properties during laser curing of light-sensitive films. In one embodiment, pulse separation reduces non-uniform growth of an oxide layer during laser oxidation of the substrate. In one embodiment, pulse separation reduces or eliminates overcuring during laser curing of semiconductor or other films.

In one embodiment, the entire substrate surface is exposed to multiple interleaved scans. In one embodiment, selected portions of the substrate surface are exposed to multiple interleaved scans.

In one embodiment, along each of a plurality of scanned lines, pulsed laser energy is deposited in non-adjacent sites, with subsequent scans depositing energy in unfilled sites. In one embodiment, two interleaved scans provide coverage of the substrate. In one embodiment, three or more interleaved scans provide coverage of the substrate. In one embodiment, in each scan, energy is deposited in non-adjacent lines, with subsequent scans depositing energy in unfilled lines. In one embodiment, every other site along each line and every other line are addressed in each scan, such that four interleaved scans provide coverage of the substrate. In one embodiment, every third site along each line and every third line are addressed in each scan, such that nine interleaved scans provide coverage of the substrate. In one embodiment, every fourth site along each line and every fourth line are addressed in each scan, such that sixteen interleaved scans provide coverage of the substrate. In one embodiment, fewer sites than every second site along each line are addressed in each scan, such that six or more interleaved scans provide coverage of the substrate. In one embodiment, fewer lines than every second line are addressed in each scan, such that six or more interleaved scans provide coverage of the substrate.

In one embodiment, a time between subsequent pulses affecting each point on the substrate is greater than a thermal diffusion time. In one embodiment, along each of a plurality of scanned lines, pulsed laser energy is deposited in non-adjacent sites, with subsequent scans depositing energy in unfilled sites. In one embodiment, in each scan, energy is deposited in non-adjacent lines, with subsequent scans depositing energy in unfilled lines.

In one embodiment, pulse spacing within each scan is greater than a thermal diffusion length. In one embodiment, along each of a plurality of scanned lines, pulsed laser energy is deposited in non-adjacent sites, with subsequent scans depositing energy in unfilled sites. In one embodiment, in each scan, energy is deposited in non-adjacent lines, with subsequent scans depositing energy in unfilled lines.

According to another aspect, the invention is directed to an apparatus for delivering pulsed laser energy to a substrate. The apparatus includes a pulsed laser for generating a beam of radiation along a path. Beam forming optics receive the beam of radiation from the pulsed laser and creating a desired beam and directing the desired beam onto the substrate. A scanner changes the beam location relative to the substrate, and a reaction chamber contains the substrate. A controller controls the pulsed laser and the scanner such that spatial and temporal pulse separation is achieved by means of multiple interleaved scans.

In one embodiment, the pulsed laser comprises a solid state laser. In one embodiment, the solid state laser comprises a diode-pumped laser. In one embodiment, the solid-state laser comprises a frequency-doubled YAG laser operating at a wavelength of 532 nm. In one embodiment, the solid-state laser comprises a frequency-tripled YAG laser operating at a wavelength of 355 nm. In one embodiment, the solid-state laser comprises a frequency-quadrupled YAG laser operating at a wavelength of 266 nm. In one embodiment, the pulsed laser operates in a wavelength range of 190 to 1070 nm

In one embodiment, the pulsed laser operates in a wavelength range of 150 to 550 nm. In one embodiment, the beam-forming optics comprise at least one of beam-attenuating, beam-correcting, beam-expanding, beam-flattening, beam-homogenizing, beam-focusing, and beam-bending optical components. In one embodiment, the beam-attenuating components comprise beam-splitting mirrors to control fluence at the substrate. In one embodiment, the beam-correcting components comprise an anamorphic corrector for changing a beam divergence in one axis to permit the same divergence and effective source point in a first and a second orthogonal axis. In one embodiment, the beam-expanding components comprise a variable, focusable expander. In one embodiment, a beam-flattening component comprises two plano-convex lenses. In one embodiment, the beam-homogenizing component comprises an array-lens “fly's eye” homogenizer and focusing lens. In one embodiment, the beam-focusing components comprise an f-theta scan lens. In one embodiment, the beam-bending components comprise bending mirrors to provide a compact optical system.

In one embodiment, the scanner comprises a galvanometric scan mirror for scanning the beam onto the substrate in one axis and a moving stage to step the substrate relative to the beam in an orthogonal axis.

In one embodiment, the scanner comprises two galvanometric scan mirrors for scanning the beam in two dimensions over the substrate.

In one embodiment, the reaction chamber comprises a window, a substrate support, one or more gas inlet ports, and one or more gas outlet ports.

In one embodiment, the substrate support comprises a vacuum chuck and a heating element.

In one embodiment, an oxidizing gas is introduced into the reaction chamber.

In one embodiment, a reducing gas is introduced into the reaction chamber.

In one embodiment, an inert gas is introduced into the reaction chamber.

In one embodiment, pulse separation reduces substrate damage.

In one embodiment, the entire substrate surface is exposed to multiple interleaved scans.

In one embodiment, selected portions of the substrate surface are exposed to multiple interleaved scans.

In one embodiment, along each of a plurality or scanned lines, pulsed laser energy is deposited in non-adjacent sites, with subsequent scans depositing energy in unfilled sites.

In one embodiment, in each scan, energy is deposited in non-adjacent lines, with subsequent scans depositing energy in unfilled lines.

According to another aspect, the invention is directed to a method for delivering pulsed electromagnetic energy to a substrate, comprising: applying the pulsed electromagnetic energy to the substrate; and spatially and temporally separating pulses of the pulsed electromagnetic energy on the substrate by performing multiple interleaved scans of the pulsed electromagnetic energy onto the substrate.

In one embodiment, pulse separation reduces thermally induced damage during pulsed electromagnetic radiation processing of the substrate.

In one embodiment, along each of a plurality of scanned lines, pulsed electromagnetic radiation energy is deposited in non-adjacent sites, with subsequent scans depositing energy in unfilled sites. In one embodiment, in each scan, energy is deposited in non-adjacent lines, with subsequent scans depositing energy in unfilled lines.

The novel pulse laser scanning method and apparatus of the invention allow the processing of sensitive surfaces without causing damage, at high throughput rates using near-visible and visible pulsed laser radiation from a small solid state laser with a system that may be operated at room temperature and room pressure. This invention enables the development of advanced semiconductor processes such as cleaning of highly sensitive low-k and other thin film surfaces that cannot now be done with conventional related art methods.

Further scope of applicability of the present invention will become apparent from the detailed description given hereinafter to be read in conjunction with the accompanying drawings. However, it should be understood that the detailed description and specific examples, while indicating preferred embodiments of the invention, are given by way of illustration only, since various changes and modifications within the spirit and scope of the invention will become apparent to those skilled in the art from this detailed description. The invention may be practiced with a variety of lasers, scan heads, beam shapes, substrate materials and processes, and enclosure configurations.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1a is a schematic top view of a substrate being scanned by a pulsed laser according to conventional methods of scanning.

FIG. 1b is a schematic view illustrating the possible damage zone that occurs when sequential pulses overlap in space when conventional methods of scanning are used. This is an example of the amount of overlap that occurs with a circular beam when the minimum possible overlap that allows full coverage of the sample is used.

FIG. 1c is a schematic top view of a substrate being scanned by a pulsed laser, with the pulses separated to avoid overlap such that approximately 9% of the substrate is not covered by the laser pulses.

FIG. 2a is a graph of the fluence profile that demonstrates the buildup of energy from an overlapped Gaussian beam where half of the energy from the previous pulse is still present when the current pulse arrives. If the pulse diameter is defined as the diameter of the Gaussian beam at the cleaning threshold, this graph matches the overlap used in FIG. 1b.

FIG. 2b is a graph of the fluence profile that demonstrates the buildup of energy from an overlapped top-hat beam where half of the energy from the previous pulse is still present when the current pulse arrives. This graph matches the overlap used in FIG. 1b.

FIG. 3a is a schematic diagram illustrating a single-scan method used by the prior art.

FIGS. 3b-3c are schematic diagrams that illustrate the simplest implementation of a scanning approach according to embodiments of the invention, in which every other and every third pulse is delivered in a different scan.

FIGS. 4a-4c are schematic diagrams that illustrate a more advanced form of the scanning approach of the invention in which the locations of the pulses in a single scan are spread as evenly as possible. Each diagram contains both a map of the final layout of the pulses and a series of diagrams that illustrate the buildup of pulses as the scanning progresses.

FIGS. 5a-5c are schematic diagrams that illustrate a method for using a higher-order scanning approach according to the invention to achieve a higher overlap while maintaining a constant pulse spacing within a single scan.

FIG. 6a is a table that illustrates the schematic layouts of multiple pulsed laser scanning approaches according to preferred embodiments of the present invention.

FIGS. 6b-6c are schematic diagrams illustrating an approach for implementing the values contained in the table of FIG. 6a.

FIG. 7a is a schematic diagram of a system and apparatus for delivering pulsed laser radiation and creating surface reactions according to an embodiment of the present invention.

FIG. 7b is a schematic diagram of one embodiment of the beam forming optics from FIG. 7a.

FIG. 7c is a schematic diagram of one embodiment of the scan head from FIG. 7a.

FIG. 8a is a graph showing an optimized Gaussian beam, and an actual profile of a Gaussian beam as outputted by the system shown in FIG. 7a.

FIG. 8b is a graph showing an optimized top-hat beam, and an actual profile of a top-hat beam as outputted by the system shown in FIG. 7a.

### DETAILED DESCRIPTION OF THE PREFERRED EMBODIMENTS

In the following description of the preferred embodiments of the invention, a method and apparatus for optimally delivering pulsed laser radiation will be detailed.

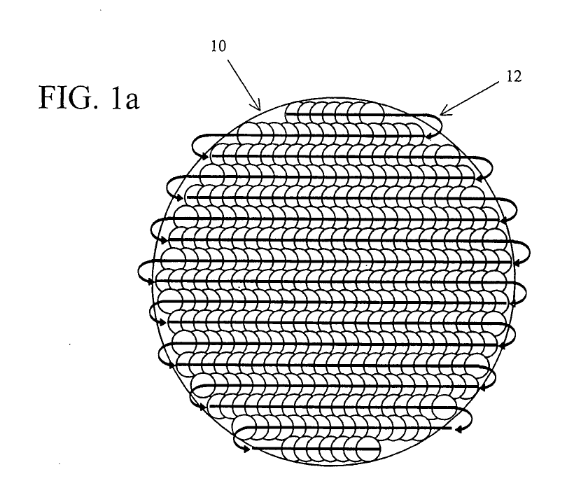

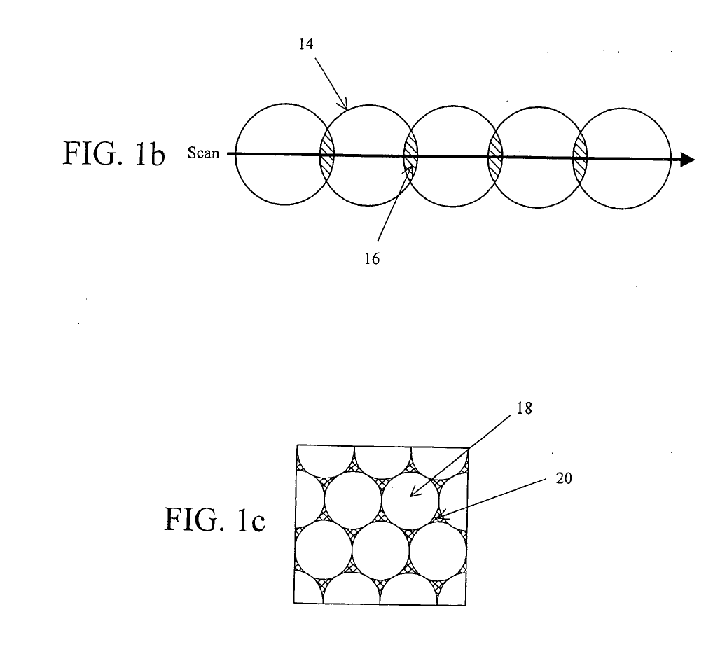

In FIG. 1a, one of several possible conventional scanning methods is illustrated, a two-dimensional serpentine or boustrophodonic scan. An alternative is to “fly back” at the end of each scanned line so that all lines are scanned in the same direction. Another method is a one-dimensional scan with the substrate stepped in the orthogonal direction.

FIG. 1b illustrates the “double exposure” that results from an attempt, using conventional scanning, to obtain complete coverage. Since the time between pulses is very short (10 to 100 μs) compared to thermal diffusion times that can be on the order of milliseconds, the overlap regions reach higher temperatures and are thereby subject to damage or other unwanted effects.

If such overlap is avoided by larger pulse-to-pulse spacing, as illustrated in FIG. 1c, then unexposed regions remain between pulses and processing is incomplete.

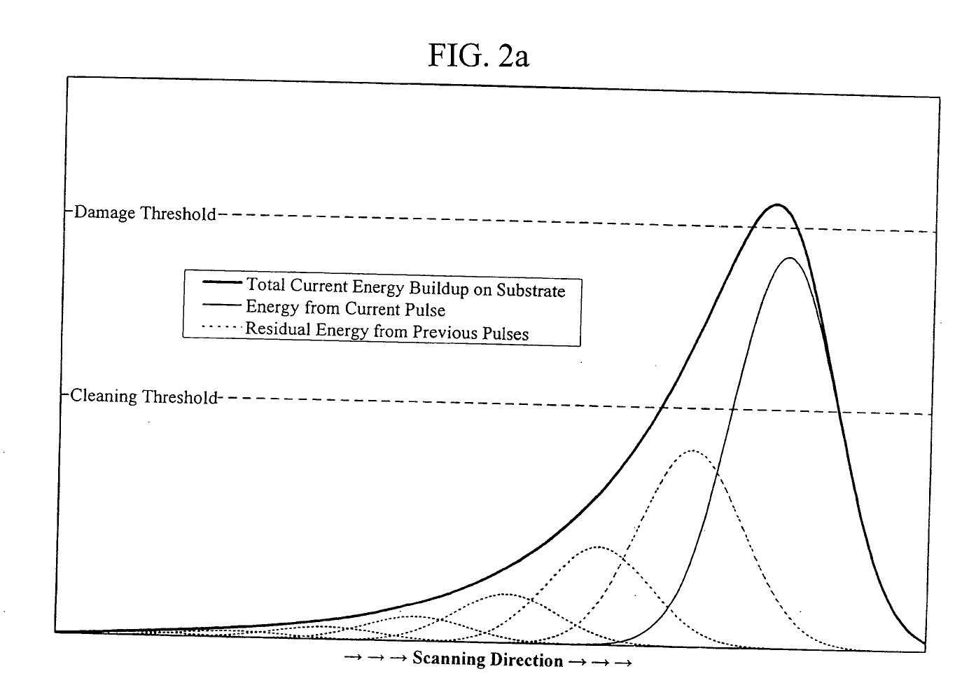

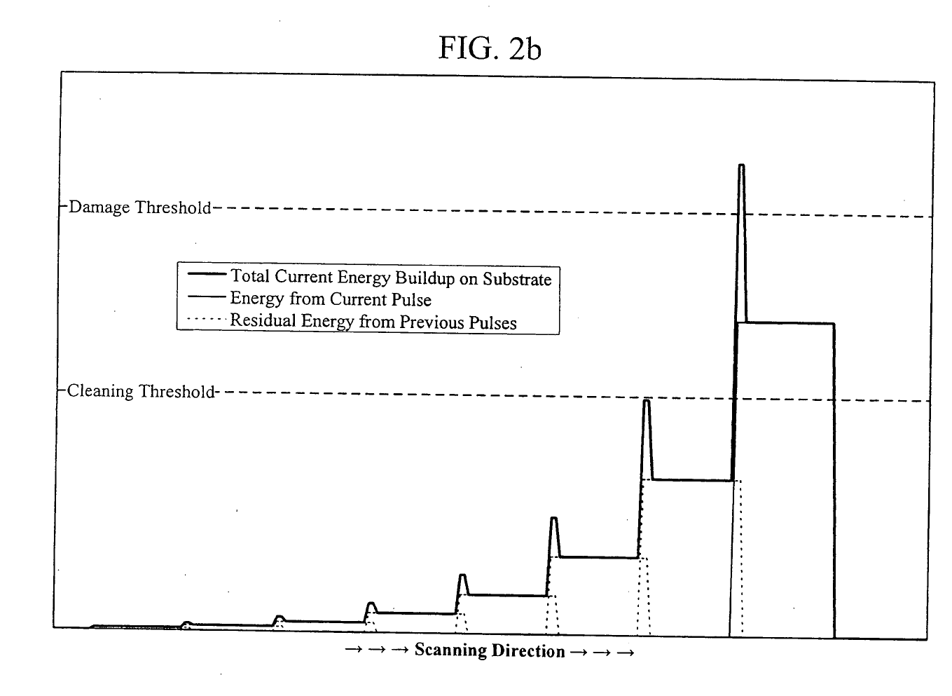

FIG. 2a (for a Gaussian beam) and FIG. 2b (for a top-hat beam) illustrate the cumulative energy build-up between pulses. Although the top-hat beam is more efficient and should result in a more uniform exposure, it generally produces more severe overlap effects than the Gaussian beam.

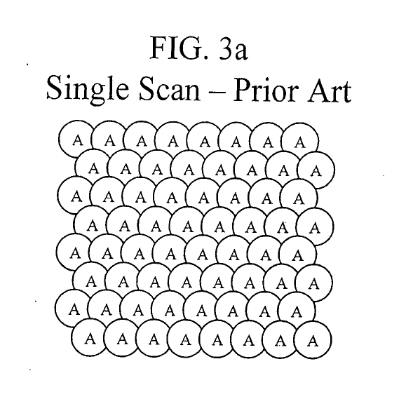

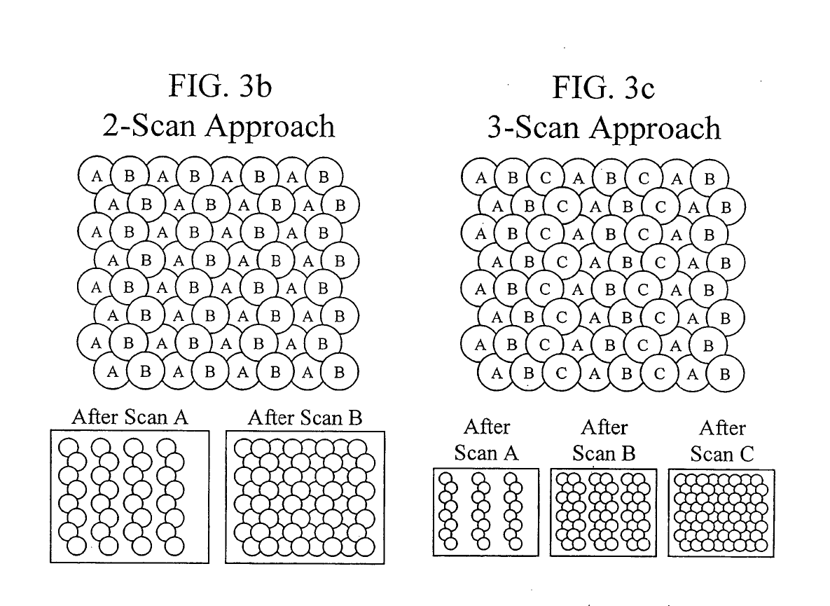

In FIGS. 3a-3c, 4a-4c, and 5a-5c, scanning methods employing prior art and various methods of the invention described herein are illustrated. In all cases, beams may be Gaussian, top-hat, or other profiles. Although a circle is used to represent each pulse, actual beams may have circular, square, hexagonal, or other shapes. The details will vary depending upon exact beam profile and shape, but the principles according to the invention are the same.

In FIG. 3a, a conventional single scan (“A”) is shown, resulting in the unwanted effects explained above. The simplest and most basic implementation of the interleaved scanning approach of the invention is shown in FIG. 3b, in which every other site on each scan line is addressed on the first “A” scan. Then a second “B” scan fills in the sites that were unaddressed during the “A” scan. Since the time between lines is much longer than the time between adjacent pulses, the overlap of “A” pulses or “B” pulses from one line to the next will take place after a much longer delay, typically tens or hundreds of milliseconds, so that minimal thermal build-up will occur. The time at any site between the “A” and “B” scans is even greater, typically many seconds, so that “A” to “B” interactions are completely negligible.

Referring to FIG. 3b, it may be the case that the time between sequential “A” (or “B”) pulses is shorter than thermal decay times so that each site is pre-heated by the previous “A” (or “B”) pulse. In that event, the approach illustrated in FIG. 3c reduces the effect by introducing a third scan, so that in each scan the pulses are 50% further apart. This method may be extended to 4 or more scans, limited only by the speed at which the beam can be scanned.

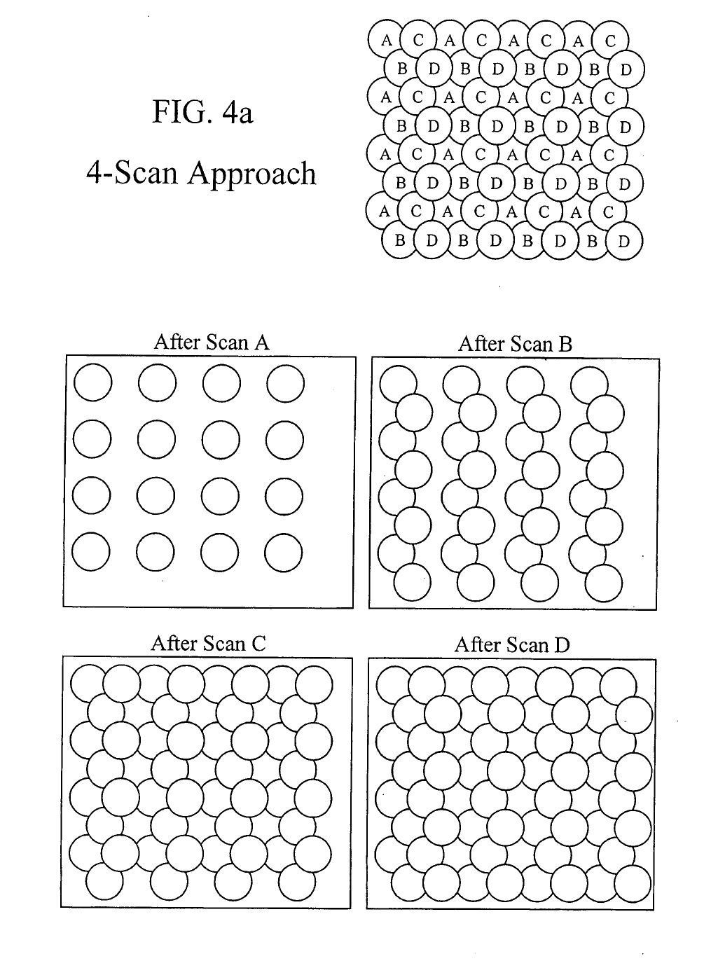

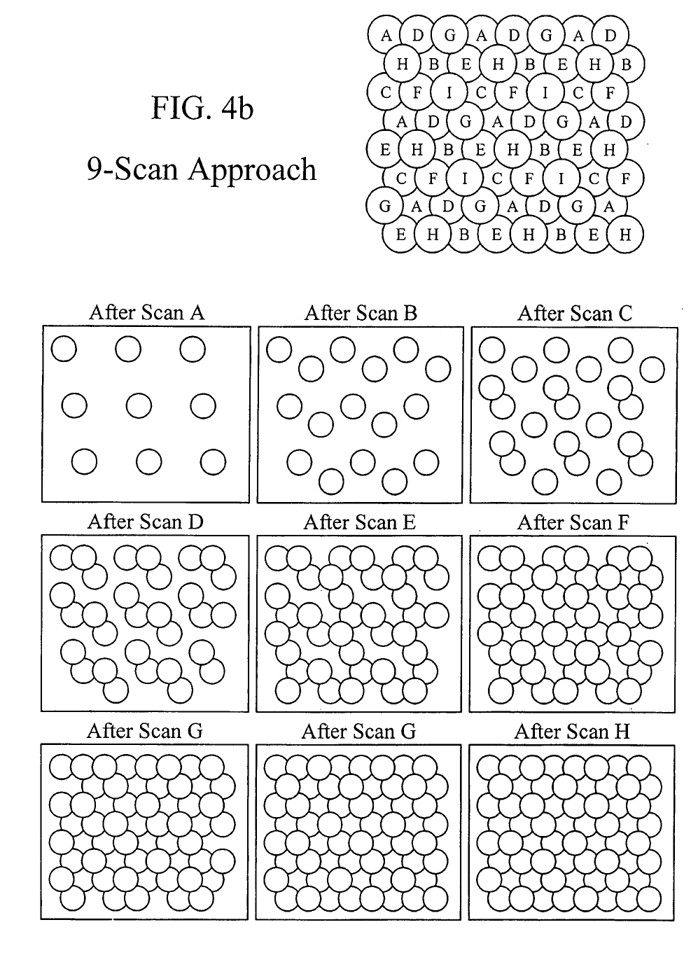

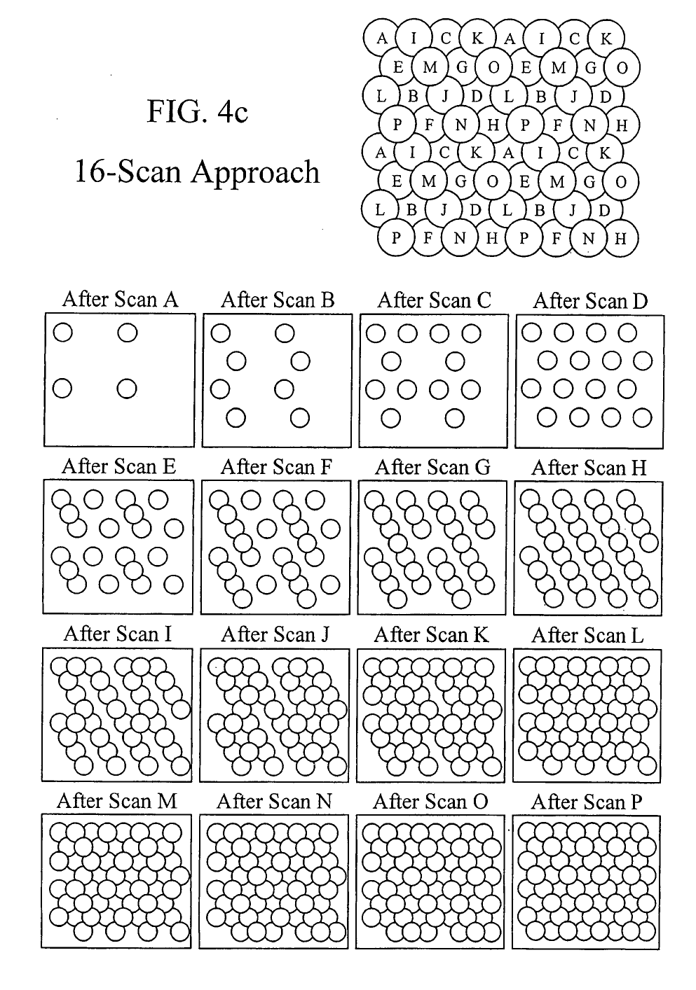

Another method of implementing interleaved pulsing in accordance with the invention is with two-dimensional interleaving, as illustrated in FIG. 4. The simplest case is a 2×2, or 4-scan approach shown in FIG. 4a. This method is particularly useful if the unwanted effects are mainly spatial, rather than temporal. An example is gas depletion, where time constants are much longer than thermal diffusion times. If each pulse depletes the reactive gas in its immediate neighborhood, then 2-dimensional pulse spacing (see “After Scan A” diagram) allows the gas to re-form between scans, so that Scan B is just as effective as Scan A. Subsequent “C” and “D” scans continue and complete the process.

If the depleted gas zone is larger, then a 3×3, or 9-scan approach, as illustrated in FIG. 4b, will reduce the effect. It will be noted that this approach requires the displacement of the starting location of each line within a single scan. The 4×4, or 16-scan approach shown in FIG. 4c avoids this complication and also further separates the scans.

In addition to gas depletion, other unwanted effects may be reduced or eliminated by these 2-dimensional interleaved pulse approaches. One example is the removal of processing debris when the reaction at the substrate is incomplete. In that case, passing the laser beam through the debris cloud above each site is avoided.

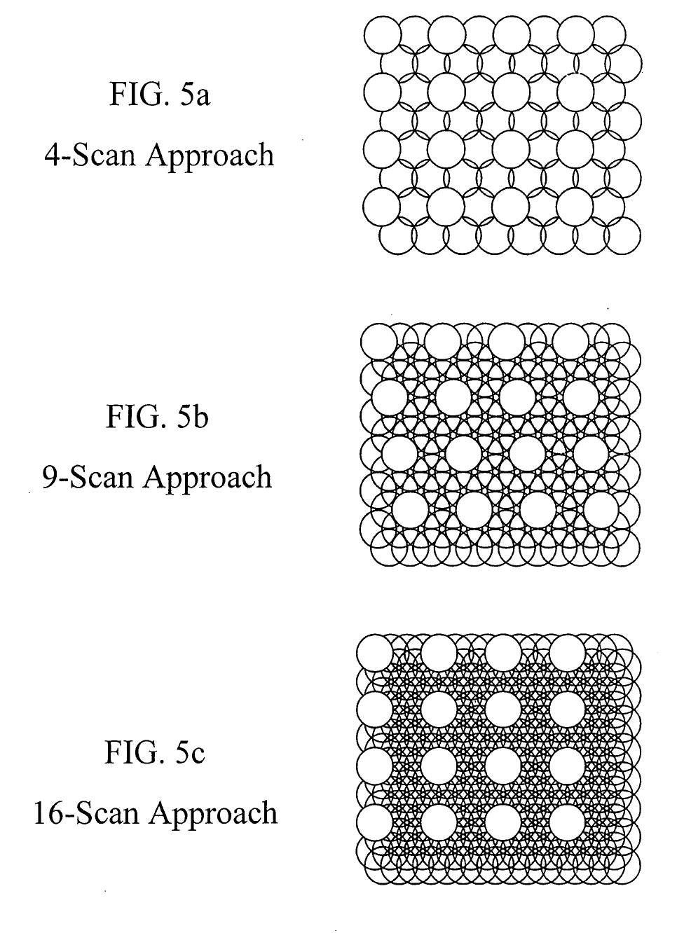

FIGS. 5a-5c illustrate another application of interleaved pulsing according to the invention, in which it is desired to deposit a large radiation dose over the substrate, while avoiding thermally-induced damage, gas depletion, or other unwanted effects. The 4-scan approach in FIG. 5a is identical to the approach of FIG. 4a, but by keeping the same pulse spacing, increasing the number of scans, and placing the scans as shown in FIG. 5b, a 9-scan approach can be used to increase the dose by a factor of 2.25.

Further dose increase, a factor of 4 over the 4-scan approach, can be obtained with the 16-scan approach shown in FIG. 5c. Again, thermal and other unwanted effects are no worse than with the 4-scan approach, but much more complete coverage is obtained. This is particularly useful if the beam is far from ideal, with “hot” and “cold” regions that could otherwise result in both unexposed and damaged sites.

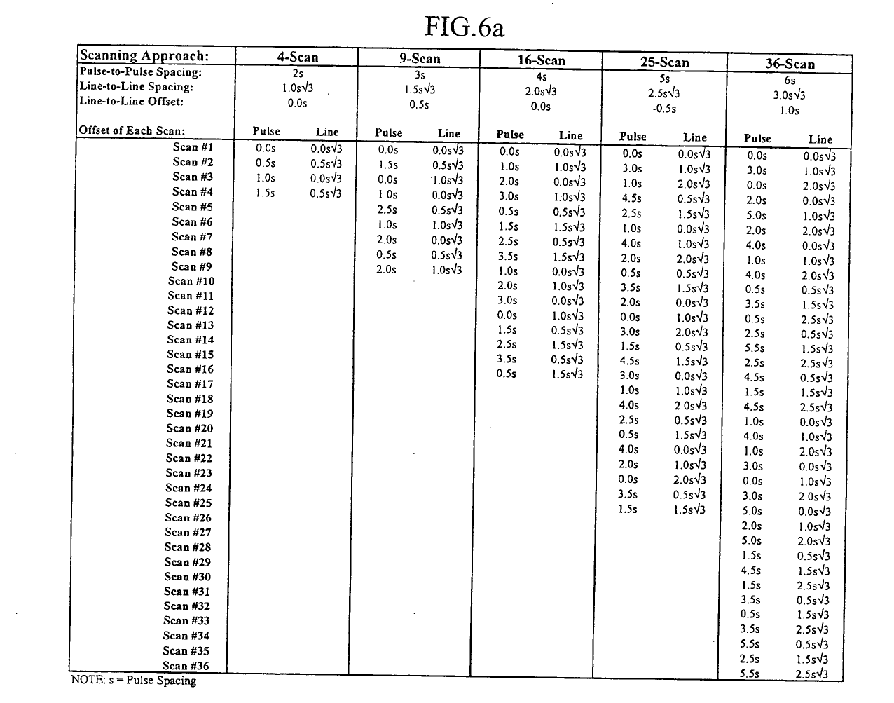

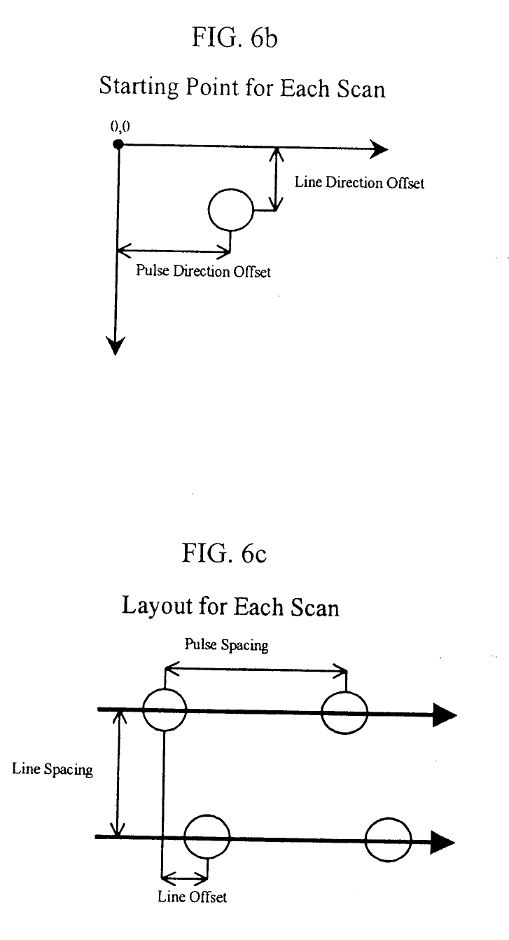

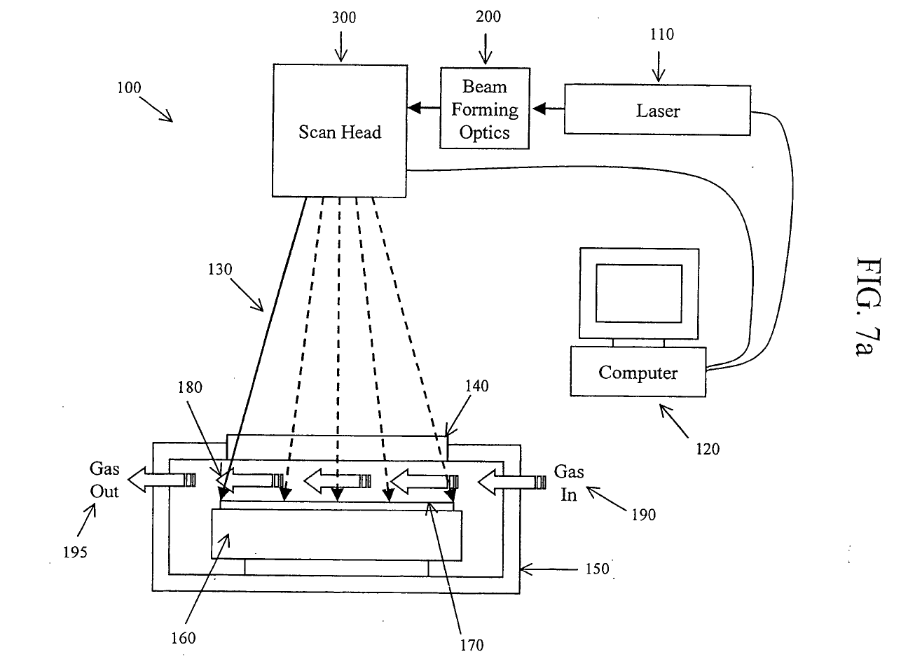

Pulse layout for the N×N approaches, where N is 2, 3, 4, 5, or 6, is tabulated in FIG. 6a. For a final pulse spacing of s, the line-to-line spacing and line-to-line offset, if any, is shown in the top section of the table. Then the starting location offset for each line scan is given, in the “Pulse” direction (along the line scan) and “Line” direction (perpendicular to the line scan). FIG. 6b defines these offsets, while FIG. 6c defines the pulse-to-pulse and line-to-line spacings. The final pulse spacing s will depend on the application, beam size, beam shape, and beam profile. For example, with an ideal circular top-hat beam and minimal complete coverage for a low-dose application, s=0.5*√3 d=0.866d, where d=beam diameter.

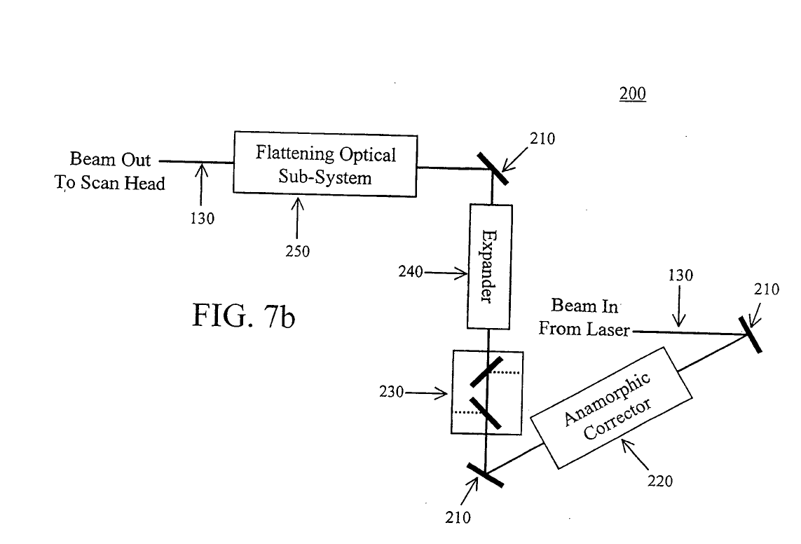

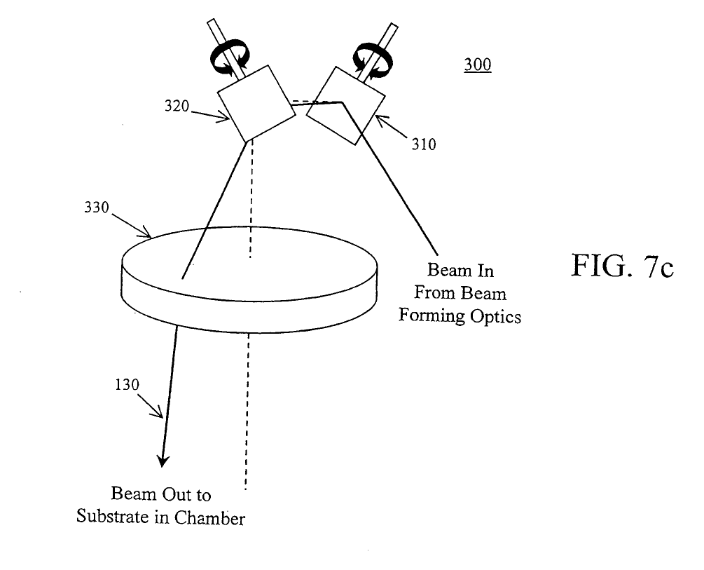

Referring to FIG. 7a, a system 100 is shown for implementing the pulsed laser scan approaches of the present invention. System 100 includes a small solid state laser 110, generating a beam of pulsed laser radiation 130 which is directed through beam forming optics 200 and into scan head 300, and from there, deflected down through quartz window 140 onto the substrate 170 which is mounted on substrate holder 160. A flow of gas is introduced into the enclosure or reaction chamber 150 of system 100 from inlet port 190, where it flows in a direction 180 over the surface of the substrate 170 and out of enclosure 150 through gas outlet port 195.

As shown in FIG. 7a, laser 110 can be a solid state diode-pumped laser operating at a wavelength in the range 350 nm to 550 nm, from the near-visible part of the electromagnetic spectrum into the visible. The 355 nm is a 3× YAG wavelength used for many of the experiments to prove the effectiveness of the present invention described herein. The 532 nm visible wavelength has also been used for removal of organic contamination by using an absorbing layer on top of the photoresist layer which conducts the 532 nm radiation into the resist layer. The 532 nm is a 2× YAG wavelength. Other wavelengths, both longer into the infrared and shorter in the ultraviolet, can be used with these gases and the pulse spreading approach to make use of the present invention in processing substrates in IC manufacturing and other applications. For example, a 4× YAG laser at 266 nm has been used to remove the photoresist layer, and for deep UV resists, this wavelength is preferred for stronger absorption of the photons into the resist layer, allowing for complete reaction of by-products and leaving behind a clean, residue-free surface. Solid state lasers are highly reliable, low loss, and easy to maintain in production, resulting in low cost of ownership, a pre-requisite for cost effective manufacturing in IC production. The primary advantages of the near visible and visible wavelengths are low scattering in the optics and low photon energy compared to prior art methods and systems. 30. The pulsed laser can operate in a wavelength range of 190 to 1070 nm. The pulsed laser can operate in a wavelength range of 150 to 550 nm.

In cleaning applications, and specifically in photoresist removal applications, the prior art systems used deep ultraviolet wavelengths of 193 nm and 248 nm, which have high photon energy and damage semiconductor surfaces when exposed. These short UV wavelengths also scatter very easily in optics, causing large losses, and therefore creating the need for very large, expensive lasers to provide sufficient energy to cleaning, oxidizing, annealing, or imaging. The use of the near-visible 355 nm and visible 532 nm laser wavelengths of the present invention allows for very high transmission of light through the window, whereas prior art short UV laser wavelengths of 193 nm and 248 nm will damage the window due to much higher photon energy, and will undergo significant beam energy losses due to scattering when going through the window. These limitations of the prior art methods and systems have prevented their acceptance in industry for organic material removal primarily.

In the non-cleaning applications of the present invention, wavelengths from deep ultraviolet to visible are suitable, depending on the gases used, their absorption coefficient, and their relative interaction with the surface being processed.

The beam forming optics 200 shown in FIG. 7b transforms the raw beam from the laser into a beam of desired size shape profile and intensity within a compact and readily aligned path. The beam forming optics 200 includes at least three bending mirrors 210 to create a compact and readily aligned optical path. The beam forming optics 200 may also include an anamorphic corrector assembly 220 to provide compensation for beam divergence in one axis so as to correct laser beam asymmetry to provide the same source point and divergence angle in both axes. The beam forming optics 200 may also include an attenuator assembly 230. In one implementation this attenuator is comprised of a pair of beam splitting mirrors to control laser fluence at the substrate.

The beam forming optics 200 may also include an expander 240 to adjust the beam size and/or divergence angle. In one embodiment the beam expander is variable and focusable and can be a model #ZBE20-1X5-355, provided by Photonic Devices, Inc. of Wyckoff, N.Y., or other similar device.

The beam forming optics 200 may also include a beam flattening optical subsystem 250 which flattens the beam by reducing the maximum-to-minimum intensity variations. In one embodiment the beam flattening optical subsystem 250 includes two plano-convex lenses. In another embodiment this component is a beam homogenizer which includes one or more “fly's-eye” array lenses and a focusing lens.

The beam is then directed into scan head module 300 shown in FIG. 7c which directs the beam 130 by using two galvo-driven mirrors 310 and 320 which provide the means to direct the beam in a variety of patterns and directions on a substrate. This allows for programmed interleaved scanning patterns stored in computer 120 to control both laser 110 and scan head 300 to scan either portions of the substrate for direct lithography imaging for example, or for complete substrate coverage as in cleaning, annealing, oxidizing or curing a surface. The scan head sub-system 300 also includes a scan lens 330 preferably a post deflection f-theta lens for planar focusing and a linear relationship between the angular position of the galvo-driven mirrors 310 and 320 and the beam's location on the substrate. In one embodiment the scan head sub-assembly includes a model “hurrySCAN14” and a scan lens model #106566, both provided by ScanLab AG, of Puchheim, Germany, or other similar device. In one embodiment the scan lens 330 can be a telecentric f-theta lens to provide a beam landing angle at the substrate 170 of less than 6°.

The beam 130 enters the process chamber enclosure 150 through quartz window 140. Inside the chamber, the gas flow 180 is directed laterally across the surface of substrate 170 to permit uniform reaction rates and efficient removal of by-products to leave behind a clean, residue free surface. Substrate support 160 may be just a simple vacuum chuck and may also contain a heater to provide a low level of thermal energy to assist is some reactions such as resist removal. Due to the use of strong oxidizing gases such as ozone, very low heat can be used, eliminating the problems of the prior art of thermal damage to heat sensitive devices, especially low-k films and thin gate oxides used on advanced IC devices. The lateral movement of the gas flow directs all by products toward the exit side of the chamber and out to the exhaust 195.

As illustrated in FIG. 7a, the gas flow will interact with the incoming laser radiation 130 which is being caused to scan from scan head 300, across substrate 170. A variety of gases can be used to create a number of surface reactions. For example, oxidizing gases such as ozone or oxygen are used to remove photoresists from damage-sensitive surfaces along with the scan approaches of the present invention. The same gases may be used to create oxidation reactions for PVD copper layers in advanced IC fabrication. Reducing gases such as hydrogen or ammonia are used for surface termination, organic film removal, or other surface conditioning reactions.

The system 100 can be operated at room temperature and ambient pressure, eliminating the need for the cost of vacuum pumps and long pump-down cycles associated with prior art systems. The low-temperature operation permits use with advanced IC devices which are increasingly sensitive to thermal environments. The system 100 also operates with a low-energy reaction, does not produce the ionizing radicals of the prior art plasma systems, and therefore will not damage IC devices, low-k films used in advanced IC devices, thin films of metal on dielectrics as used on photomasks, or optical devices. Related art systems using RF energy are known to cause electrical and physical damage, especially on the more advanced low-k films and thin gate oxides.

System 100 can deliver non-damaging energy and chemistry to provide a variety of useful surface reactions needed in the fabrication of integrated circuits, thin film heads, flat panel displays and optical devices, such as CD masters. These reactions include the use of oxygen and ozone or ammonia or hydrogen for the removal of photoresist layers such as hardbaked resist or ion implanted photoresist; oxide formation using mixtures of oxygen and ozone; and inert gases such as nitrogen or helium for annealing of films such as PVD copper on silicon wafers for example.

System 100 is, due to the use of these ‘green’ gases, and by avoiding the need for halogens or corrosive and toxic chemicals of the prior art, providing an environmentally sound method and apparatus for industrial use.

The system 100, combined with the pulsed laser scan approaches of the present invention, provides a complete process capability to enable this novel invention to be used in manufacturing.

The system described above and illustrated in FIG. 7a was used for the following experiments. The 355 nm 3× YAG laser used is a Lightwave Q301-HD. The beam is 1.7 mm¹ in diameter at the output of the laser.

TABLE 1
Laser Output

| | | | Pulse Energy at |
|---|---|---|---|
| Repetition Rate | Pulse Width¹ | Laser Pulse Energy¹ | Sample Plane² |
| 10 kHz | 30 ns | 1.31 mJ | 1.13 mJ |
| 15 kHz | 39 ns | 0.87 mJ | 0.76 mJ |
| 20 kHz | 46 ns | 0.60 mJ | 0.54 mJ |
| 25 kHz | 55 ns | 0.43 mJ | 0.40 mJ |
| 30 kHz | 62 ns | 0.32 mJ | 0.29 mJ |

¹From manufacturer's test report
²Laboratory measurements

The cleaning problem to which the invention is applicable as a solution included of a quarter inch thick quartz plate with 500-1,000 Å of PVD chrome and a thick 100 Å AR coating on top of the chrome coated with less than 1,000 Å of Rohm and Haas 1818 photoresist. A series of experiments were performed to optimize the scanning parameters so as to prevent the chrome from cracking during laser removal of the photoresist. When an optimized parameter set was discovered a second sample was scanned to confirm the results. Instead of confirming the results, this sample had extreme damage to the chrome layer. After scanning a third sample with similar results to the second sample, it was determined that variations in the thickness of the photoresist layer were causing different amounts of heat to be stored in the photoresist on each sample. Since this parameter was inconsistent, it was obvious that a method for scanning the sample needed to be developed that would enable complete coverage of the sample where pulses that are sequential in time would not overlap in space.

The standard application that has been used as a benchmark for determining system performance is the removal of 7,000Å-10,000 Å of hardbaked Rohm and Haas 1818 photoresist from silicon wafers. This particular exemplary application is not damage sensitive, so several pulses may land sequentially in the same location without affecting the silicon substrate, but it is very important that cleaning be achieved in the shortest possible time.

The previous best-known method for the removal of this photoresist involved the use of an expanded Gaussian beam and two passes with the laser with the conventional scanning method. The two passes were scanned orthogonally to each other to try to ensure complete laser coverage. Complete removal of the photoresist was achieved in 180 seconds.

The following parameters were used for this experiment demonstrating a conventional scanning method:
Beam Profile: Gaussian
Reaction Diameter: approximately 500 μm
Laser Repetition Rate: 10 kHz
Scan Speed: 1750 mm/s
Line Spacing: 0.2 mm
Scanning Method: Bidirectional
Sample was scanned with 2 orthogonal passes
Wafer Size: 200 mm diameter
Substrate: Silicon
Chuck Temperature: 90° C.
Chamber Pressure: 130 Torr
Gas Mixture: 15% Ozone (by wt.) in Oxygen
Gas Flow: 9 slm

This cleaning application was further optimized through the use of both beam forming optics that transformed the Gaussian beam profile to a “top-hat” (uniform) beam profile, and through the use of the scanning approach to increase both reaction efficiency and to achieve complete cleaning of the sample in less time.

Due to limitations in the current scanning software, several aspects of the implementation of the scanning approach are not fully optimized. The limitations are as follows: Each scanned line must start on the same side of the wafer, therefore there is a “flyback time” of 8 μs for each scanned line based on the fact that the laser returned to the beginning of the line at 25,000 mm/s. Limitations in the scanning software also required a 200 mm by 200 mm square to be scanned to cover the circular wafer. Despite these limitations, the photoresist was completely removed from the wafer in only 115 seconds. If the “flyback time” was eliminated the scanning time would be only 96 seconds, and if the “flyback time” was eliminated and the wafer was scanned using a circular scanning area 200 mm in diameter the total scanning time would be only 76 seconds.

The following parameters were used for this experiment demonstrating the scanning approach with an optimized beam profile:
Beam Profile: Top-Hat
Beam Diameter: 417 μm
Laser Repetition Rate: 12 kHz
Single-Scan Pulse Spacing: 400 μm
Final Pulse Spacing: 200 μm
Scanning Approach: 4-Scan
Flyback Speed: 25,000 mm/s
Fluence Range: 660-990 mJ/cm²
Wafer Size: 200 mm diameter
Substrate: Silicon
Chuck Temperature: 90° C.
Chamber Pressure: 30 Torr
Gas Mixture: 18% Ozone (by wt.) in Oxygen
Gas Flow: 4 slm

A large portion of the time improvement was due to the fact that with the conventional method each individual location on the wafer was scanned with between 8 and 14 pulses with the conventional method to ensure complete coverage, essentially over-scanning the wafer to make sure no area was missed, and to remove particles left behind by the inefficient reaction with the Gaussian beam. The scanning approach of the invention carefully places the pulses in a hexagonal grid pattern so that complete coverage can be achieve with each individual location on the wafer being scanned with between 3 and 7 pulses. It should be noted that some of this improvement was due to the optimization of the beam shape since the use of a top-hat beam creates a more complete reaction at each site so that less cleanup is required.

Another improvement to this process made with the 4-scan approach of the invention was the improved availability of reactive gas species in the gas reaction zone (GRZ). With the conventional scanning method most of the photoresist was removed in a single pass with highly overlapped (65% overlap) pulses. Since the first pass was highly overlapped the reaction was dampened by lack of reactive gas species, resulting in a large number of particles that had to be removed with a cleanup pass. In the experiment that was performed using the 4-scan approach of the invention there was only a small amount of overlap within each pass (4%). Because of this, each ablation plume within the GRZ was spaced farther apart from the others where it could obtain a sufficient quantity of reactive gas species to fully react. This improvement could be directly observed by comparing the brightness of the GRZ for each reaction because the visible light is a byproduct of the combustion reaction. The GRZ for the reaction using the 4-scan approach was significantly brighter than the reaction with the conventional single-scan-per-pass method.

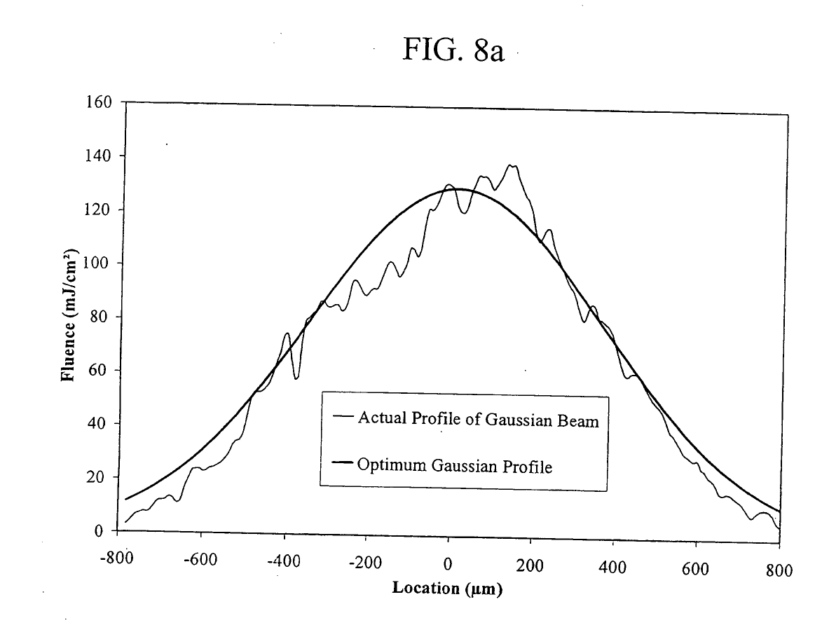

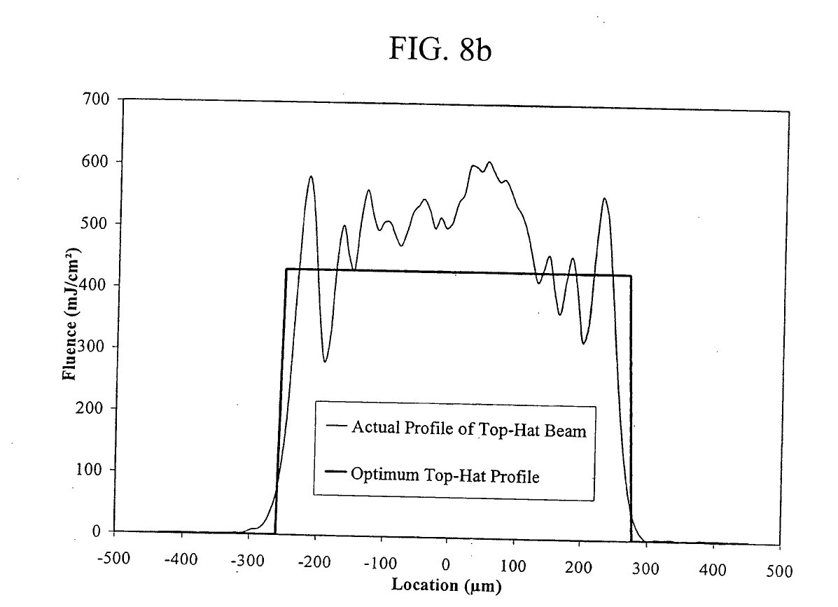

In a third cleaning example a silicon sample was coated in 6500 nm of Clariant AZ4330 photoresist and baked at 120° C. for 45 minutes. This produced an extremely tough and thick coating. Removal was achieved by using a 256-scan approach according to the invention to achieve a very tight coverage range of between 260 and 266 pulses at any given site on the sample. By comparison, a conventional scan with a pulse overlap of 50% in each direction and where each scan is orthogonal to the previous scan will have a coverage range of between 186 and 372 pulses at any given site on the sample if the same average coverage range is used. This means that complete removal could not be achieved without the use of the scanning approach of the invention because of the need for a uniform pulse distribution since the actual profile of the top-hat beam was not ideal. It had a peak-to-average deviation ((peak−average)÷average) of approximately 50% and a RMS deviation of approximately 15%. A typical profile of a top-hat beam outputted from the optical system along with an optimum top-hat beam is shown in FIG. 8b.

The following parameters were used for this experiment:
Beam Profile: Top-Hat
Beam Diameter: 512 μm
Laser Repetition Rate: 16 kHz
Single-Scan Pulse Spacing: 480 μm
Final Pulse Spacing: 30 μm
Scanning Approach: 256-Scan
Flyback Speed: 25,000 mm/s
Fluence Range: 370-470 mJ/cm²
Wafer Size: 150 mm diameter
Substrate: Silicon
Chuck Temperature: 90° C.
Chamber Pressure: 225 Torr
Gas Mixture: 18% Ozone (by wt.) in Oxygen
Gas Flow: 4 slm

In a fourth cleaning example a sample with 1,000 Å of silicon dioxide on a silicon substrate was coated in hardbaked Rohm and Haas 1818 photoresist. The sample was then scanned using a 16-scan approach according to the invention with a top-hat beam to remove the photoresist. The photoresist was successfully removed with minimal damage of the silicon dioxide layer. In no place was the silicon dioxide removed such that the underlying silicon was exposed. This had never been accomplished with conventional scanning methods.

The following parameters were used for this experiment:
Beam Profile: Top-Hat
Beam Diameter: 417 μm
Laser Repetition Rate: 15 kHz
Single-Scan Pulse Spacing: 400 μm
Final Pulse Spacing: 100 μm
Scanning Approach: 16-Scan
Fluence Range: 700-860 mJ/cm²
Flyback Speed: 25,000 mm/s
Wafer Size: 200 mm diameter
Chuck Temperature: 90° C.
Chamber Pressure: 30 Torr
Gas Mixture: 100% Ammonia
Gas Flow: 8 slm

In a fifth experiment an oxide layer was grown on a sample that included approximately 1,500 Å of PVD copper on a silicon substrate. Oxide growth is a dose driven application, and a Gaussian profile is optimized for dose driven applications. In this experiment, use of the scanning approach allowed for the delivery of a large dose of laser energy with approximately 1% variation across the entire surface at a very low fluence level to prevent damage to the new oxide layer. The profile of the Gaussian beam used in this experiment is shown in FIG. 8a along with an optimized Gaussian beam.

Also of note in this example is the fact that the chuck is not heated because a thin oxide layer forms on the entire wafer when it is heated, since the process is performed in a strongly oxidizing atmosphere. By keeping the wafer at room temperature, oxide can be selectively grown to the desired thickness only on portions of the wafer where the laser is scanned.

The following parameters were used in this experiment for copper oxide growth:
Beam Profile: Gaussian
1/e² Beam Diameter: 1,444 μm
Laser Repetition Rate: 15 kHz
Single-Scan Pulse Spacing: 400 μm
Final Pulse Spacing: 50 μm
Scanning Approach: 64-Scan
Fluence Range: 110-130 mJ/cm²
Dose Range: 35,200-35,600 mJ/cm²
Flyback Speed: 25,000 mm/s
Wafer Size: 200 mm diameter
Chuck Temperature: 30° C.
Chamber Pressure: 30 Torr
Gas Mixture: 18% Ozone (by wt.) in Oxygen
Gas Flow: 4 slm

In a sixth experiment a silicon wafer coated with 5 μm of MicroChem SU-8 2005 negative acting photoresist was directly imaged using the system described in FIG. 7a. Since the goal was to create an image using the scanning approach, parallel lines were scanned with and without the scanning approach so that both sets of lines had the same final pulse spacing even though the pulses arrived in a different order. After the wafer was exposed it was given a post exposure bake and developed in ethyl lactate.

The areas that were scanned without the use of the scanning approach had a ridge down the center where the laser energy built up to a level that caused the photoresist to overcure and bulge upwards. The areas that were scanned using the linear 7-scan approach were smooth on top.

The wafer was only processed in a low-pressure oxygen atmosphere because the setup of the hardware is based around a cleaning application with a vacuum pump that is difficult to bypass and where nitrogen is not plumbed in as a standard process gas. Since there is no reaction with the surrounding atmosphere the wafer could be processed at atmospheric pressure in either an inexpensive inert gas, such as nitrogen, or in the ambient atmosphere.

The following parameters were used in this experiment to implement the scanning approach of the invention for the purpose of imaging parallel lines:
Beam Profile: Top-Hat
Beam Diameter: 140 μm
Laser Repetition Rate: 100 kHz
Single-Scan Pulse Spacing: 140 μm
Final Pulse Spacing: 20 μm
Scanning Approach: Linear 7-Scan
Peak Fluence: 110 mJ/cm²
Flyback Speed: 25,000 mm/s
Wafer Size: 200 mm diameter
Chuck Temperature: 30° C.
Chamber Pressure: 150 Torr
Gas Mixture: 100% Oxygen
Gas Flow: 4 slm

In a seventh experiment, 1,500 Å of PVD copper on a silicon substrate was successfully annealed using the apparatus described in FIG. 6 using an inert atmosphere to prevent the melted copper from reacting and/or oxidizing. After the sample was processed it was inspected under an optical microscope at magnification levels ranging from 50×-500× where it was determined that the sample had been melted.

The following parameters were used in this experiment to anneal copper:
Beam Profile: Top-Hat
Beam Diameter: 417 μm
Laser Repetition Rate: 15 kHz
Single-Scan Pulse Spacing: 400 μm
Final Pulse Spacing: 100 μm
Scanning Approach: 16-Scan
Fluence Range: 700-860 mJ/cm²
Flyback Speed: 25,000 mm/s
Wafer Size: 200 mm diameter
Chuck Temperature: 90° C.
Chamber Pressure: 30 Torr
Gas Mixture: 100% Nitrogen
Gas Flow: 8 slm

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method for delivering pulsed laser energy to a substrate, comprising:
applying the pulsed laser energy to the substrate; and
spatially and temporally separating pulses of the pulsed laser energy on the substrate by performing multiple interleaved scans of the pulsed laser energy onto the substrate.

2. The method of claim 1, wherein pulse separation reduces thermally induced damage during laser cleaning of a substrate.

3. The method of claim 1, wherein pulse separation reduces gas depletion during laser cleaning in a reactive gas atmosphere.

4. The method of claim 1, wherein pulse separation reduces unwanted thermally induced change in chemical properties during laser curing of light-sensitive films.

5. The method of claim 1, wherein pulse separation reduces non-uniform growth of an oxide layer during laser oxidation of the substrate.

6. The method of claim 1, wherein pulse separation reduces or eliminates overcuring during laser curing of semiconductor or other films.

7. The method of claim 1, wherein the entire substrate surface is exposed to multiple interleaved scans.

8. The method of claim 1, wherein selected portions of the substrate surface are exposed to multiple interleaved scans.

9. The method of claim 1, wherein along each of a plurality of scanned lines, pulsed laser energy is deposited in non-adjacent sites, with subsequent scans depositing energy in unfilled sites.

10. The method of claim 9, wherein two interleaved scans provide coverage of the substrate.

11. The method of claim 9, wherein three or more interleaved scans provide coverage of the substrate.

12. The method of claim 9, wherein in each scan, energy is deposited in non-adjacent lines, with subsequent scans depositing energy in unfilled lines.

13. The method of claim 12, wherein every other site along each line and every other line are addressed in each scan, such that four interleaved scans provide coverage of the substrate.

14. The method of claim 12, wherein every third site along each line and every third line are addressed in each scan, such that nine interleaved scans provide coverage of the substrate.

15. The method of claim 12, wherein every fourth site along each line and every fourth line are addressed in each scan, such that sixteen interleaved scans provide coverage of the substrate.

16. The method of claim 12, wherein fewer sites than every second site along each line are addressed in each scan, such that six or more interleaved scans provide coverage of the substrate.

17. The method of claim 12, wherein fewer lines than every second line are addressed in each scan, such that six or more interleaved scans provide coverage of the substrate.

18. The method of claim 1, wherein a time between subsequent pulses affecting each point on the substrate is greater than a thermal diffusion time.

19. The method of claim 18, wherein along each of a plurality of scanned lines, pulsed laser energy is deposited in non-adjacent sites, with subsequent scans depositing energy in unfilled sites.

20. The method of claim 19, wherein in each scan, energy is deposited in non-adjacent lines, with subsequent scans depositing energy in unfilled lines.

21. The method of claim 1, wherein pulse spacing within each scan is greater than a thermal diffusion length.

22. The method of claim 21, wherein along each of a plurality of scanned lines, pulsed laser energy is deposited in non-adjacent sites, with subsequent scans depositing energy in unfilled sites.

23. The method of claim 22, wherein in each scan, energy is deposited in non-adjacent lines, with subsequent scans depositing energy in unfilled lines.

24. An apparatus for delivering pulsed laser energy to a substrate, comprising:
a pulsed laser for generating a beam of radiation along a path;
beam forming optics for receiving the beam of radiation from the pulsed laser and creating a desired beam and directing the desired beam onto the substrate;
a scanner for changing the beam location relative to the substrate;
a reaction chamber containing the substrate; and
a controller for controlling the pulsed laser and the scanner such that spatial and temporal pulse separation is achieved by means of multiple interleaved scans.

25. The apparatus of claim 24, wherein the pulsed laser comprises a solid state laser.

26. The apparatus of claim 25, wherein the solid state laser comprises a diode-pumped laser.

27. The apparatus of claim 25, wherein the solid-state laser comprises a frequency-doubled YAG laser operating at a wavelength of 532 nm.

28. The apparatus of claim 25, wherein the solid-state laser comprises a frequency-tripled YAG laser operating at a wavelength of 355 nm.

29. The apparatus of claim 25, wherein the solid-state laser comprises a frequency-quadrupled YAG laser operating at a wavelength of 266 nm.

30. The apparatus of claim 24, wherein the pulsed laser operates in a wavelength range of 190 to 1070 nm.

31. The apparatus of claim 24, wherein the pulsed laser operates in a wavelength range of 50 to 550 nm.

32. The apparatus of claim 24, wherein the beam-forming optics comprise at least one of beam-attenuating, beam-correcting, beam-expanding, beam-flattening, beam-homogenizing, beam-focusing, and beam-bending optical components.

33. The apparatus of claim 32, wherein the beam-attenuating components comprise beam-splitting mirrors to control fluence at the substrate.

34. The apparatus of claim 32, wherein the beam-correcting components comprise an anamorphic corrector for changing a beam divergence in one axis to permit the same divergence and effective source point in a first and a second orthogonal axis.

35. The apparatus of claim 32, wherein the beam-expanding components comprise a variable, focusable expander.

36. The apparatus of claim 32, wherein a beam-flattening component comprises two plano-convex lenses.

37. The apparatus of claim 32, wherein the beam-homogenizing components comprise an array-lens “fly's eye” homogenizer and focusing lens.

38. The apparatus of claim 32, wherein the beam-bending components comprise bending mirrors to provide a compact, easily alignable optical system.

39. The apparatus of claim 24, wherein the scanner comprises two galvanometric scan mirrors for scanning the beam in two dimensions over the substrate and a scan lens.

40. The apparatus of claim 39, wherein the scan lens component comprises a post deflection f-theta scan lens.

41. The apparatus of claim 40, wherein the f-theta lens is telecentric.

42. The apparatus of claim 24, wherein the reaction chamber comprises a window, a substrate support, one or more gas inlet ports, and one or more gas outlet ports.

43. The apparatus of claim 42, wherein the substrate support comprises a vacuum chuck and a heating element.

44. The apparatus of claim 24, wherein an oxidizing gas is introduced into the reaction chamber.

45. The apparatus of claim 24, wherein a reducing gas is introduced into the reaction chamber.

46. The apparatus of claim 24, wherein an inert gas is introduced into the reaction chamber.

47. The apparatus of claim 24, wherein pulse separation reduces substrate damage.

48. The apparatus of claim 24, wherein the entire substrate surface is exposed to multiple interleaved scans.

49. The apparatus of claim 24, wherein selected portions of the substrate surface are exposed to multiple interleaved scans.

50. The apparatus of claim 24, wherein along each of a plurality or scanned lines, pulsed laser energy is deposited in non-adjacent sites, with subsequent scans depositing energy in unfilled sites.

51. The apparatus of claim 50, wherein in each scan, energy is deposited in non-adjacent lines, with subsequent scans depositing energy in unfilled lines.

52. A method for delivering pulsed electromagnetic energy to a substrate, comprising:
applying the pulsed electromagnetic energy to the substrate; and
spatially and temporally separating pulses of the pulsed electromagnetic energy on the substrate by performing multiple interleaved scans of the pulsed electromagnetic energy onto the substrate.

53. The method of claim 52, wherein pulse separation reduces thermally induced damage during pulsed electromagnetic radiation processing of the substrate.

54. The method of claim 52, wherein along each of a plurality of scanned lines, pulsed electromagnetic radiation energy is deposited in non-adjacent sites, with subsequent scans depositing energy in unfilled sites.

55. The method of claim 54, wherein in each scan, energy is deposited in non-adjacent lines, with subsequent scans depositing energy in unfilled lines.
